(19) United States
(12) Patent Application Publication
(10) Pub. No.: US 2025/0341743 A1
(43) Pub. Date: Nov. 6, 2025

(54) LIGHT SOURCE ASSEMBLY AND LED DEVICE, DISPLAY DEVICE AND BACKLIGHT MODULE HAVING THE SAME

(71) Applicant: Shenzhen Jufei Optoelectronics Co., Ltd., Shenzhen (CN)

(72) Inventors: Lianjian DENG, Shenzhen (CN); Xin JIN, Shenzhen (CN); Donghan WEI, Shenzhen (CN); Hongbo SU, Shenzhen (CN); Yanming CHEN, Shenzhen (CN); Pingru SUN, Shenzhen (CN); Kejin WU, Shenzhen (CN); Chuanhu WANG, Shenzhen (CN); Zhonghua JIN, Shenzhen (CN); Jintao CAO, Shenzhen (CN); Mingquan LI, Shenzhen (CN); Meizheng XING, Shenzhen (CN)

(73) Assignee: Shenzhen Jufei Optoelectronics Co., Ltd., Shenzhen (CN)

(21) Appl. No.: 18/032,935

(22) PCT Filed: Oct. 22, 2021
(86) PCT No.: PCT/CN2021/125717

§ 371 Date: Sep. 29, 2023

(30) Foreign Application Priority Data
Oct. 23, 2020 (CN) 202011147363.X
Oct. 28, 2020 (CN) 202022438741.1
Oct. 30, 2020 (CN) 202011192424.4
Nov. 30, 2020 (CN) 202011384242.7
Dec. 14, 2020 (CN) 202011470165.7

(51) Int. Cl. G02F 1/1335; G02F 1/13357

(52) U.S. Cl. CPC G02F 1/133607; G02F 1/133608; G02F 1/133612; G02F 1/133614

(57) ABSTRACT

A light source assembly is applicable to an LED device, a display device, or a backlight module. The light source assembly includes a carrier plate and a plurality of light sources arranged above the carrier plate in an array. Packaging problems (for example, how to improve a soldering yield of light source packaging) of the light sources may be solved through a packaging structure of the light source assembly. Moreover, based on the improved packaging structure of the light source assembly, the manufactured light source assembly is applicable to the LED device, the display device, a touch screen structure module of the display device, or the backlight module, and the carrier plate and the plurality of light sources have excellent packaging characteristics.

### TECHNICAL FIELD

This application generally relates to light emitting assemblies, and more specifically, to application of LEDs.

### RELATED ART

Currently, a light emitting diode (LED) is usually used as a light source of a backlight module in a display device. However, display devices in electronic products gradually becoming light and thin, but the traditional LED can no longer satisfy the demand for a light and thin design. Therefore, currently, micro LED displays are increasingly popular in the market. The micro LED displays have advantages such as ultra-thin design, HDR technology, high resolution, high contrast, high brightness, and high color gamut.

### SUMMARY

### Technical Problem

Extremely high requirements are imposed on packaging structures of and manufacturing technologies for chips of micro LEDs due to a small size and large consumption of the chips. The inventor found that some problems exist in the packaging structure of the micro LEDs. For example, the chips cannot be accurately soldered to positions on corresponding pads, a packaging structure of the chips and a carrier plate (or a support) affect a light outgoing effect, and a soldering structure has a problem of an open circuit of electrical connection. These packaging problems lead to low reliability and hinder introduction of the products in the mass market. The inventor has developed a packaging structure to resolve the above problems. The improved light source packaging structure expands the application field of micro LEDs, and may be applied to different light source devices (such as display devices, touch screen structure modules, or backlight modules), which can realize the light and thin design and application of the light source devices.

### Technical Solution

In view of the above, the present invention provides a light source assembly, including a carrier plate and a plurality of light sources arranged above the carrier plate in an array.

In some embodiments, the light source assembly includes an LED device, and the LED device includes the carrier plate. The carrier plate includes a concave support. A step structure is arranged on an inner side of each of two protruding ends of the concave support. A metal layer is arranged on each of the step structures. An optical assembly is fitted to the step structures. A solder layer is arranged at a position of each of two ends of the optical assembly fitted to the step structures. At least one of the light sources is fixed to an inner bottom of the concave support. Electrodes of the light source are connected to electrodes of the concave support through metal wires (for example, gold wires). The concave support and the optical assembly are sealed to form a sealed vacuum space. Each of the metal layers and each of the solder layers together form a eutectic layer.

In some embodiments, the light source assembly further provides a backlight module. The backlight module further includes a light guide plate. The light guide plate is mounted to the carrier plate. The light guide plate includes a side surface and a first surface and a second surface opposite to each other. The first surface is connected to the carrier plate. The side surface is connected to the first surface and the second surface. A dimming assembly is opposite to the side surface or the first surface. Light emitted by the dimming assembly is incident onto the light guide plate through the side surface or the first surface and emitted through the second surface.

In some embodiments, the light source assembly further provides a display device. The display device further includes a display panel and the above backlight module.

In some embodiments, the above light source assembly, the LED device applied to the light source assembly, and the light source structure of the light source assembly are all applicable to the backlight module.

In some embodiments, the display device further includes a plurality of non-visible light emitting chips and a plurality of light receiving chips. The carrier plate is divided into a first region and a second region surrounding the first region. The plurality of light sources are arranged in the first region, where the plurality of light sources are a plurality of blue light flip-chips. The plurality of non-visible light emitting chips located on two adjacent sides of the first region and the plurality of light receiving chips located on the other two adjacent sides of the first region are arranged in the second region. The plurality of non-visible light emitting chips are in a one-to-one correspondence with the plurality of light receiving chips.

In some embodiments, each of the light sources of the light source assembly is an LED chip. The LED chip includes a substrate and a chip body arranged on a side of the substrate. A semiconductor layer is arranged on the chip body. The semiconductor layer includes an N-type semiconductor layer and a P-type semiconductor layer. A soldering structure is arranged on a side of the semiconductor layer facing away from the substrate. The soldering structure includes a first electrode layer. A second electrode layer is arranged on a side of the first electrode layer facing away from the substrate. The second electrode layer completely covers the first electrode layer. A third electrode layer is arranged on a side of the second electrode layer facing away from the first electrode layer. The second electrode layer reacts with a target solder that permeates the third electrode layer.

The present invention provides a light source assembly applicable to an LED device, a backlight module, a display device (including a touch screen structure module), which has a wide range of application.

The present invention is described in detail below with reference to the drawings and specific embodiments, which are not construed as a limitation on the present invention.

### BENEFICIAL EFFECT OF THE INVENTION

### Beneficial Effect

The light source assembly of the present application is applicable to an LED device, a display device, or a backlight module. The light source assembly includes a carrier plate and a plurality of light sources arranged above the carrier plate in an array. Packaging problems (for example, how to improve a soldering yield of light source packaging) of the light sources may be solved through a packaging structure of the light source assembly. Moreover, based on the improved packaging structure of the light source assembly, the manufactured light source assembly is applicable to the LED device, the display device, a touch screen structure module of the display device, or the backlight module, and the carrier plate and the plurality of light sources have excellent packaging characteristics.

### BRIEF DESCRIPTION OF THE DRAWINGS

### Drawing Descriptions

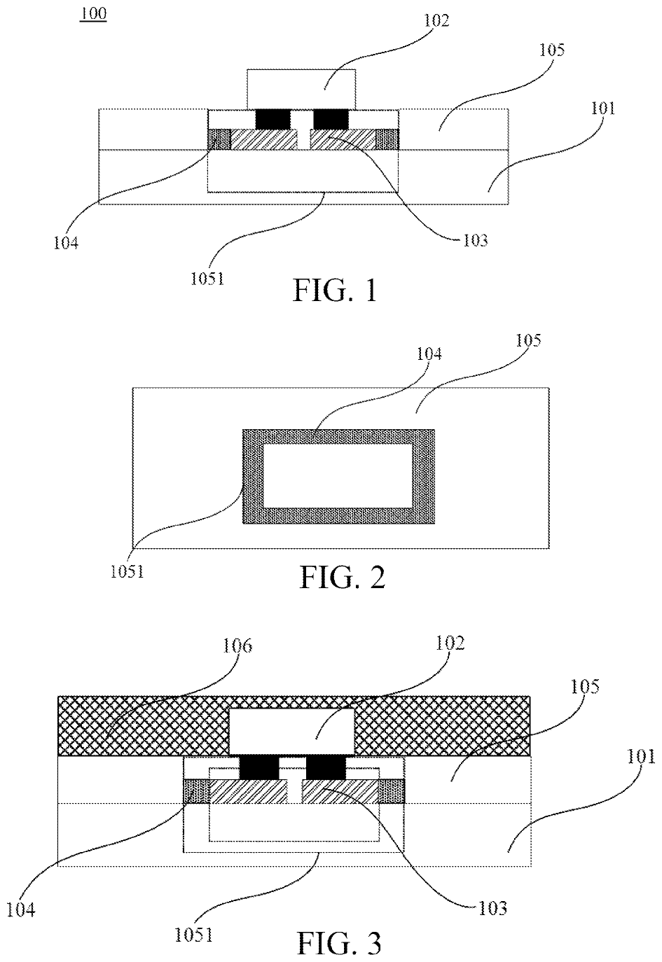

FIG. 1 is a schematic cross-sectional structural diagram of a light source assembly according to Embodiment I.

FIG. 2 is a top view of the light source assembly according to Embodiment I.

FIG. 3 is a schematic cross-sectional structural diagram of another light source assembly according to Embodiment I.

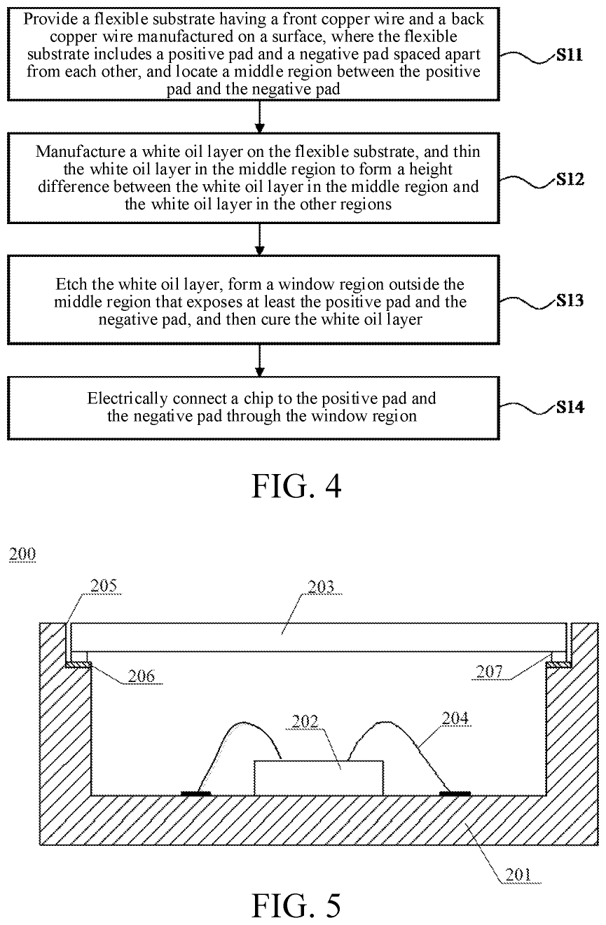

FIG. 4 is a flowchart of manufacture of a flexible printed circuit board according to Embodiment I.

FIG. 5 is a schematic cross-sectional structural diagram of an LED device according to Embodiment II.

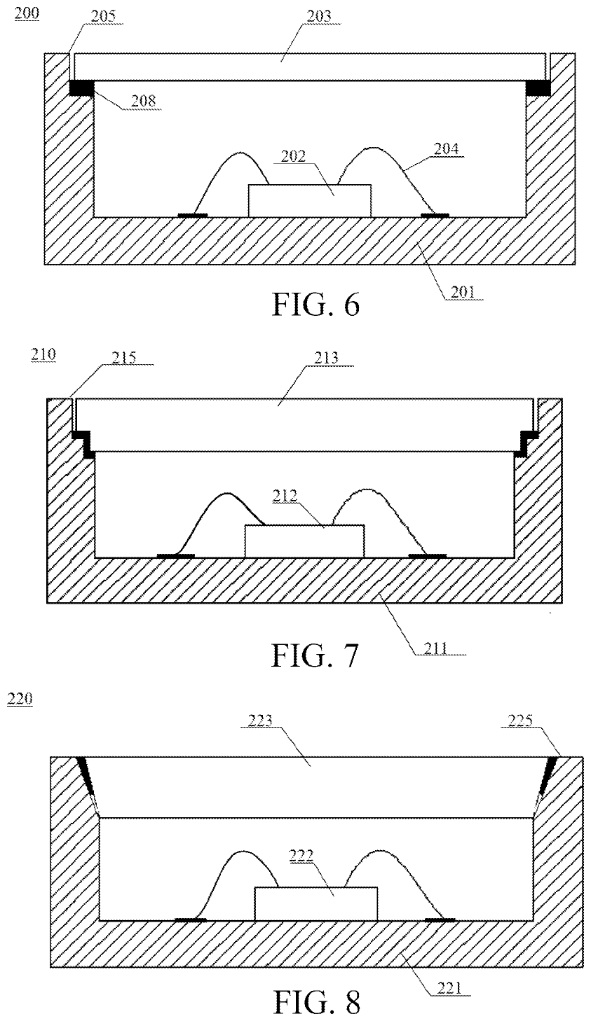

FIG. 6 is a schematic cross-sectional structural diagram of another LED device (II) according to Embodiment II.

FIG. 7 is a schematic cross-sectional structural diagram of another LED device (III) according to Embodiment II.

FIG. 8 is a schematic cross-sectional structural diagram of another LED device (IV) according to Embodiment II.

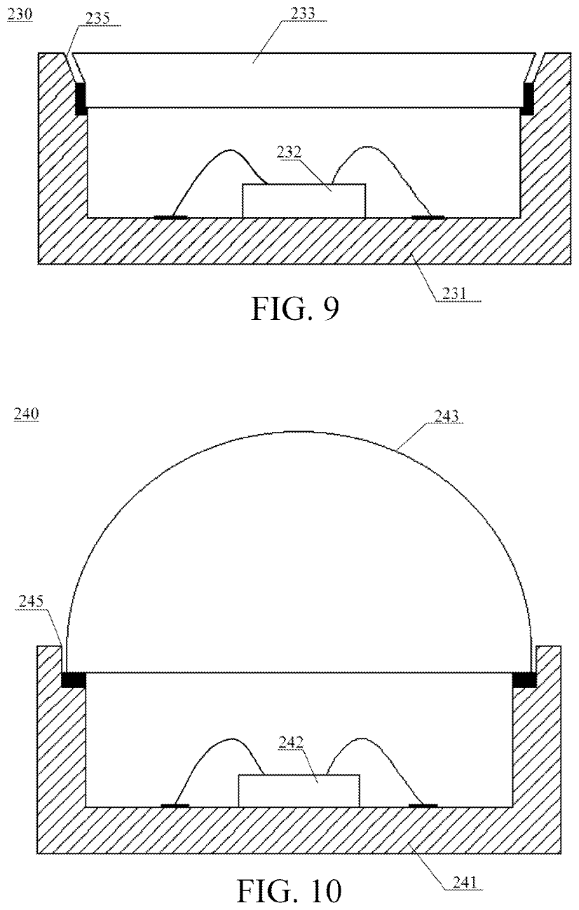

FIG. 9 is a schematic cross-sectional structural diagram of another LED device (V) according to Embodiment II.

FIG. 10 is a schematic cross-sectional structural diagram of another LED device (VI) according to Embodiment II.

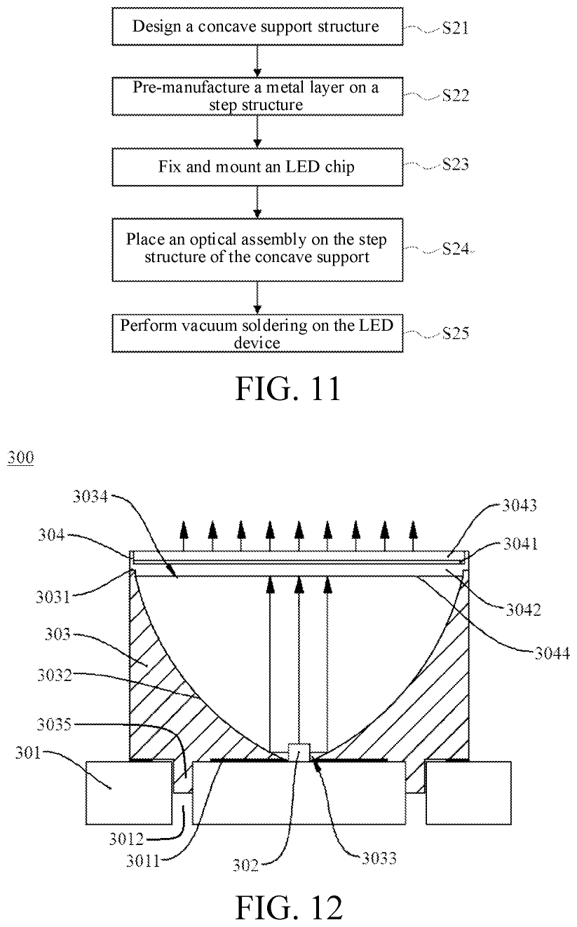

FIG. 11 is an LED device packaging flowchart according to Embodiment II.

FIG. 12 is a schematic cross-sectional structural diagram of a light source assembly according to Embodiment III.

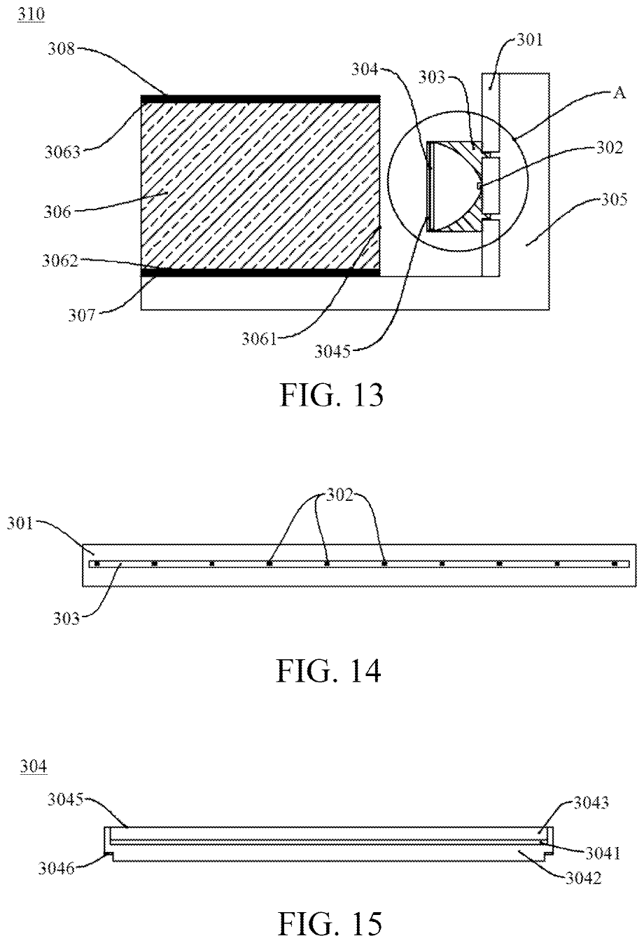

FIG. 13 is a schematic cross-sectional structural diagram of a backlight module according to Embodiment III.

FIG. 14 is a top view of a part A of the backlight module according to Embodiment III.

FIG. 15 is a schematic structural diagram of a dimming assembly according to Embodiment III.

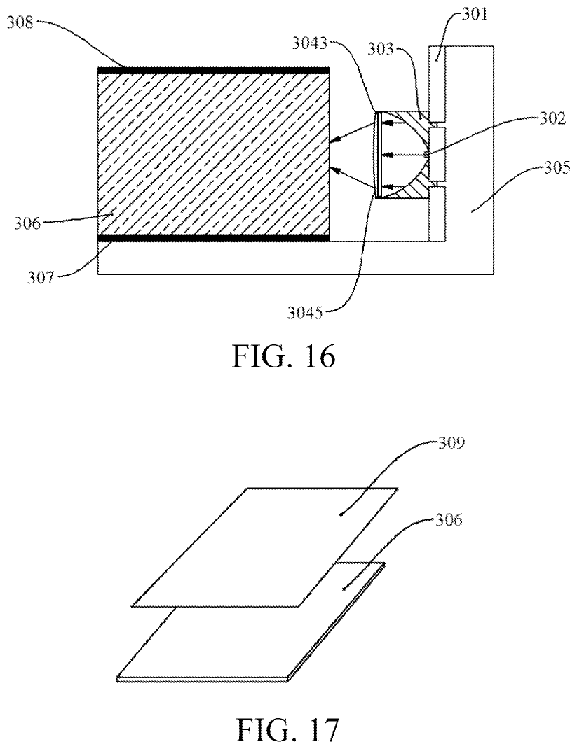

FIG. 16 is a schematic cross-sectional structural diagram of a backlight module (II) according to Embodiment III.

FIG. 17 is a schematic structural diagram of a display device according to Embodiment III.

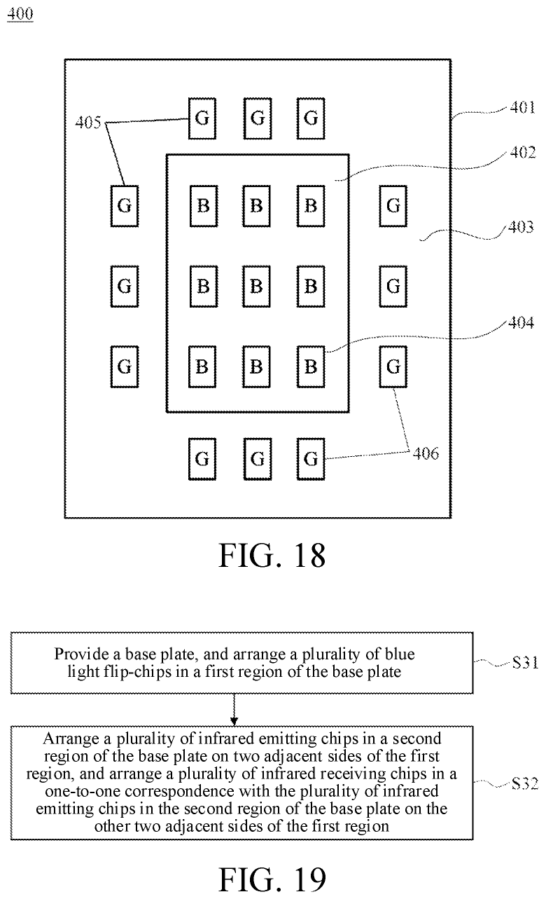

FIG. 18 is a schematic structural diagram of a touch screen structure module of the display device according to some Embodiment IV.

FIG. 19 is a schematic flowchart of a method for manufacturing the touch screen structure module of the display device according to Embodiment IV.

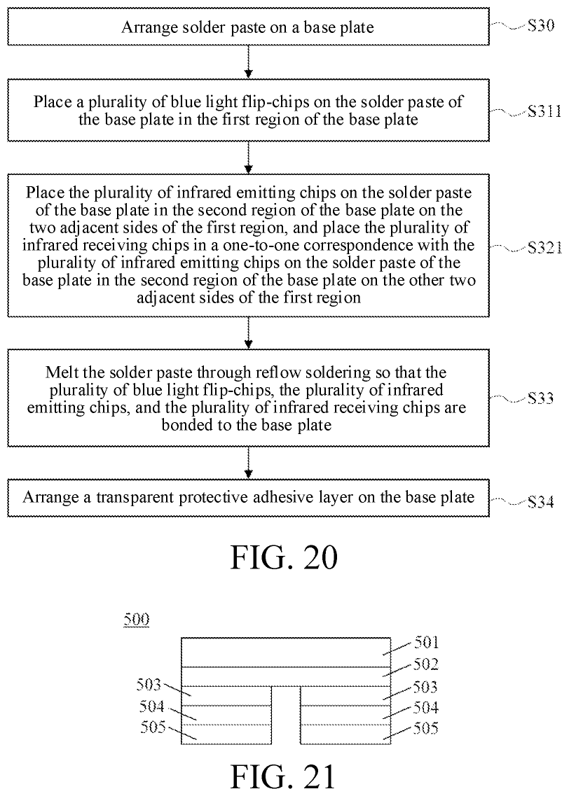

FIG. 20 is a schematic flowchart of another method for manufacturing the touch screen structure module of the display device according to Embodiment IV.

FIG. 21 is a schematic structural diagram of a light source according to Embodiments I-IV.

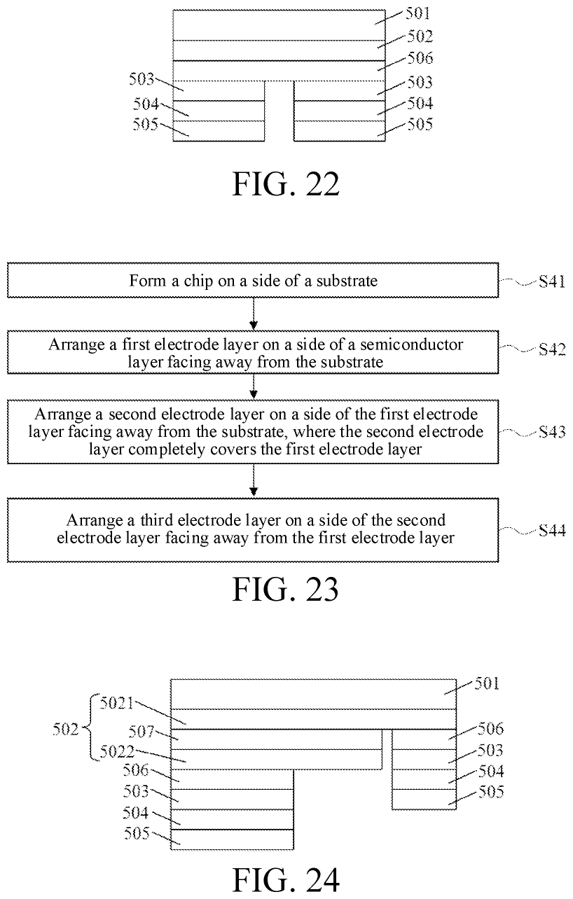

FIG. 22 is a schematic structural diagram of a light source (II) according to Embodiments I-IV.

FIG. 23 is a schematic flowchart of a light source manufacturing method according to Embodiments I-IV.

FIG. 24 is a schematic structural diagram of a light source (III) according to Embodiments I-IV.

### DETAILED DESCRIPTION

### Implementations of the Invention

In order to make the purpose, technical solutions, and advantages of the present invention clearer, embodiments of the present invention are described in further detail through specific implementations with reference to the drawings. It should be understood that the specific embodiments described herein are used to explain but not to limit the present invention.

It should be understood that the embodiments of the present invention are described below with reference to the drawings for a clear understanding, so they should be considered as exemplary description. The terms “in an embodiment” or “in some embodiments” in the description are not limited to specific or identical embodiments. A person skilled in the art should know that various changes, combinations, or adjustments may be made to the embodiments of the present invention without departing from the scope and spirit of the present invention.

### Embodiment I

FIG. 1 is a schematic cross-sectional structural diagram of a light source assembly according to Embodiment I. As shown in FIG. 1, this embodiment provides a light source assembly. The light source assembly 100 includes a carrier plate and a light source. In some embodiments, the carrier plate provides bearing and supporting functions, and may include a support, a base plate, or a circuit board. In this embodiment, the carrier plate may be a circuit board 101, and the light source may be a chip 102. The circuit board 101 includes a plurality of pads 103 configured for soldering the chip 102, and an insulation portion 104 is arranged around the pads 103. A solder mask window 1051 is further arranged on the circuit board 101. The solder mask window 1051 exposes a part of the pads 103 and extends to expose a part of the insulation portion 104. A solder mask layer 105 is arranged on a surface of the circuit board 101 except for the solder mask window 1051.

It should be noted that the circuit board 101 provides bearing and supporting functions and is configured to provide power. In some embodiments, the circuit board 101 is configured to provide an electrical driving signal for the chip 102. In this embodiment, the chip 102 may be at least one of a light emitting diode (LED), a submillimeter light emitting diode (mini LED) (or small-pitch LED), a micro light emitting diode (micro LED), and a nanoscale LED, which are examples but not limitations. The chip 102 and the circuit board 101 are manufactured separately. A surface of the circuit board 101 includes a plurality of pads 103 configured for soldering a micro LED. The chip 102 is transferred to a top of the pads 103 of the circuit board 101 after manufacture, and is soldered to the circuit board 101 through processes such as reflow soldering, so that the chip 102 can be driven to emit light by controlling an input signal of the circuit board 101. In this embodiment, the chip 102 may be but is not limited to a flip-chip.

In practical implementations, the circuit board 101 may be a printed circuit board (PCB for short). The PCB includes an electronic circuit and an insulation layer. The insulation layer exposes the pads 103 in the electronic circuit for soldering the chip 102 and covers the other pads. Alternatively, the circuit board 101 may be an array substrate formed by manufacturing a thin film transistor driving circuit on a substrate. A surface of the array substrate has connecting electrodes (that is, the pads 103 in the window) connected to the thin film transistor driving circuit. Electrodes of the chips 102 are soldered to the connecting electrodes in a one-to-one correspondence. The substrate of the circuit board 101 may be made of a flexible material to form a flexible display device.

In some embodiments, the circuit board 101 is in the shape of a plate, and preferably, overall rectangular or square. A length of the circuit board 101 is in a range of 200 mm to 800 mm, and a width is in a range of 100 mm to 500 mm. According to a size of the display device, the backlight module may include a plurality of circuit boards 101, and backlight is provided between the circuit boards 101 by splicing. The backlight module includes an edge-lit backlight module and a direct-lit backlight module. In order to avoid optical problems caused by the splicing of circuit boards 101, a splicing seam between adjacent circuit boards 101 needs to be minimized, or even seamless splicing is required. In some embodiments, the circuit board 101 may be a flexible printed circuit board, but the present invention is not limited thereto.

The solder mask layer 105 covers the circuit board 101. The solder mask layer 105 may be a protective layer (not shown in the figure) above the circuit board 101. When a reflective material is coated on the surface of the circuit board 101, the protective layer provides a reflective function, which can reflect back light that is incident on a side of the circuit board 101, thereby improving the utilization efficiency of the light.

In some embodiments, materials such as white oil may be used for the solder mask layer 105. A window is provided on the solder mask layer 105 to further expose the pads 103 on the circuit board 101. The pads 103 include a positive pad and a negative pad. Window regions corresponding to the positive pad and the negative pad need to have the equal area, so that the chip 102 can be accurately and effectively soldered to the pads 103.

Specifically, FIG. 4 is a flowchart of manufacture of a flexible printed circuit board according to Embodiment I. As shown in FIG. 4, the circuit board 101 is a flexible printed circuit board, for example. A manufacturing method includes the following steps:

Step S11: Providing a flexible substrate having a front copper wire and a back copper wire manufactured on a surface, where the flexible substrate includes a positive pad and a negative pad spaced apart from each other, and locating a middle region between the positive pad and the negative pad.

Step S12: Manufacturing a white oil layer on the flexible substrate, and thinning the white oil layer in the middle region to form a height difference between the white oil layer in the middle region and the white oil layer in the other regions, where the thinning of the white oil layer in the middle region includes: stamping the white oil layer in the middle region by using a corresponding stamping die or etching the white oil layer.

Step S13: Etching the white oil layer, forming a window region outside the middle region that exposes at least the positive pad and the negative pad, and then curing the white oil layer, where the etching of the white oil layer includes: grabbing a center of the middle region, and etching the white oil layer from a boundary of the middle region toward two sides or a periphery by using the center of the middle region as a reference, to expose the positive pad and the negative pad.

Preferably, in some embodiments, a plurality of solder mask windows 1051 may be formed directly or through digital inkjet printing.

Step S14: Electrically connecting the chip 102 to the positive pad and the negative pad through the window region.

Specifically, before soldering, the chip 102 may be moved to a position above the corresponding pads 103 through mechanical transfer. A mechanical arm for transferring the chip 102 transfers the chip 102 to the corresponding position above the circuit board 101 according to a nominal value of the window on the circuit board 101. Since a size of the chip 102 is in the micron order, a precision of the window on the circuit board 101 needs to be very high. If the pads 103 in the window are not aligned, poor soldering of the chip 102 may be caused. Therefore, exposing only the positive pad and the negative pad may result in an inaccurate window. In this case, the positive pad and the negative pad of the pads formed by exposing copper from the window of the pads do not satisfy the soldering requirements of the chip 102, resulting in poor soldering of the chip 102.

FIG. 2 is a top view of the light source assembly according to Embodiment I. In order to resolve the above problem, as shown in FIG. 2, on the basis of exposing the positive pad and the negative pad, the solder mask window 1051 extends to expose the surrounding insulation portion 104. A width of the exposed insulation portion 104 may be in a range of 30-60 μm.

As shown in FIG. 1 and FIG. 2, the window range is expanded without affecting the soldering effect of the pads 103. Even if the window region is inaccurate to a certain extent, the window range of the pads 103 is sufficient for completely exposing the positive pad and negative pad of the pads 103, so that the chip 102 can be successfully soldered to the positive pad and negative pad of the pads 103, thereby improving the soldering yield of the chip 102.

In order to recognize a patch polarity, a foolproof design of an asymmetric line is used. The pads 103 include the positive pad and the negative pad, and a line connected to the positive pad and a line connected to the negative pad in the circuit board 101 are asymmetric lines. The design of the asymmetrical line helps recognize the patch polarity.

A separation region is arranged between the positive pad and the negative pad to separate and insulate the positive pad from the negative pad, and at least one bent portion is arranged in the separation region. In this way, the anti-warping ability of the PCB, the flatness during a printing process, the printing yield, and the service life of steel mesh can be improved.

The solder mask window 1051 includes the separation region, the insulation portion 104, and the pads 103 between the separation region and the insulation portion. A width of each of the pads 103 between the separation region and the insulation portion 104 is greater than ½ of a width of the chip 102.

FIG. 3 is a schematic cross-sectional structural diagram of another light source assembly according to Embodiment I. As shown in FIG. 3, in some embodiments, the circuit board 101 further includes a protective layer 106. The protective layer 106 covers a surface on a side of the solder mask layer 105 facing away from the circuit board 101. The protective layer 106 is configured to package the chip 102, which effectively prevents the chip 102 from adversities such as fall-off and wetness. Materials of the protective layer 106 include silica gel, epoxy resin, or other colloidal materials with a high transmittance. In actual application, the protective layer may be formed on the surface of the chip 102 through spraying or dot coating. Specifically, the protective layer 106 may be manufactured through whole-surface spraying, which is more efficient. In actual application, the chip 102 may alternatively be packaged through dot coating with a colloidal material on the chip 102. The dot coating packaging can save colloidal materials, and can flexibly control a glue coating amount, and is more suitable.

The circuit board 101 provided in some embodiments includes a plurality of pads 103 configured for soldering the chip 102. An insulation portion 104 is arranged around the pads 103. A solder mask window 1051 is further arranged on the circuit board 101. The solder mask window 1051 exposes a part of the pads 103 and extends to expose a part of the insulation portion 104. A solder mask layer 105 is arranged on a surface of the circuit board 101 except for the solder mask window 1051. According to the circuit board 101 provided in the present invention, the insulation portion 104 is arranged around the pads 103, and the window range is designed to include the pads 103 and the insulation portion, so that the window range is expanded. Since the expanded window range is the insulation portion 104, a size of the exposed pads 103 is not affected even though the window range is expanded. In this way, the window range is made more precise without affecting the soldering effect of the pads 103, thereby improving the soldering yield of the chip 102.

### Embodiment II

FIG. 5 is a schematic cross-sectional structural diagram of an LED device according to Embodiment II. Embodiment II is an LED device 200 based on the light source assembly. As shown in FIG. 5, the light source assembly 200 includes a carrier plate 201, a light source 202, and an optical assembly 203. In some embodiments, the carrier plate 201 includes a concave support 201, and the light source 202 may be an LED chip. The light source 202 is fixed to an inner bottom of the concave support 201. Electrode of the light source 202 are connected to electrodes of the concave support 201 through metal wires 204 (such as gold wires). In other embodiments, the electrodes of the light source 202 may be connected to the electrodes of the concave support 201 through silver glue. The connection method is not limited thereto, as long as currents can be formed and connected between the electrodes of the light source 202 and the electrodes of the concave support 201. A step structure 205 is arranged on an inner side of each of two protruding ends of the concave support 201. A metal layer 206 is pre-manufactured on each of the step structures 205. The optical assembly 203 is fitted to the step structures 205. A solder layer 207 is arranged at a position of each of two ends of the optical assembly 203 fitted to the step structures 205.

In some embodiments, the concave support 201 and the optical assembly 203 are sealed in vacuum through a vacuum soldering system or a vacuum oven, or may be sealed in vacuum through a vacuum reflow soldering device, to form a vacuum state inside the LED device 200. That is to say, the concave support 201 and the optical assembly 203 are sealed to form a sealed vacuum space. Each of the metal layers 206 and each of the solder layers 207 together form a eutectic layer. In some embodiments, the concave support 201 may be a combination of a circuit board and a wire support, and the support may be any of a ceramic support, an SMC support, an EMC support, a PCT support, and a PPA support.

In some embodiments, the concave support 201 is made of a ceramic material. The ceramic concave support is an SMD ceramic concave support with a surface coating. The coating may be an Au or Ag coating.

In some embodiments, the step structures 205 are L-shaped step structures. It should be understood that specific structural forms of the step structures 205 are not limited to the L-shaped step structures 205 in this embodiment. Instead, the specific forms of the step structures 205 may be flexibly arranged according to an actual need.

In some embodiments, the light source 202 is fixed at a center of the bottom of the concave support 201 through silver glue or silicone resin glue, and the light source 202 is soldered with Au wires, so that the electrodes of the light source 202 are connected to the electrodes of the concave support 201.

The metal layers 206 are pre-manufactured on the step structures 205 of the concave support 201. In this embodiment, the metal layers 206 are gold-plated layers, silver-plated layers, or copper-plated layers. The specific metal material of the metal layers 206 is not limited in this embodiment, and a proper metal material may be flexibly selected as the metal coating according to actual application.

In some embodiments, the optical assembly 203 may be any of a diffractive optical element (DOE), a light diffuser, a quartz lenses, and a glass plate, or may be any combination thereof. This is not limited in this embodiment, and a proper material may be flexibly selected as the optical assembly according to a requirement of actual application. The optical assembly 203 may be a flat or hemispherical optical assembly. As shown in FIG. 5 to FIG. 9, the optical assembly 203 in this embodiment is a flat optical assembly. The solder layers 207 pre-arranged at the positions of the optical assembly 203 fitted to the step structures 205 of the concave support 201 at least partially cover a surface of each of the step structures 205, so that the light emitting effect of the device can be prevented from being affected by the solder layers 207 as a result of diffusing to regions other than the step structures 205 after melting in a subsequent vacuum soldering packaging process. In some embodiments, a thickness of the solder layers 207 is preferably in a range of 2-5 μm, and the solder layers 207 are AuSn alloy.

FIG. 6 is a schematic cross-sectional structural diagram of another LED device (II) according to Embodiment II. As shown in FIG. 6, in this embodiment, the concave support 201 and the optical assembly 203 are put into a vacuum soldering system or vacuum oven for vacuum packaging. The air inside the eutectic vacuum furnace or the vacuum oven is pumped out to reach a vacuum state, and then the LED device 200 is heated at a temperature of 280° C.-320° C. to reach a melting point of the AuSn alloy, so that the solder layers are melted and combined with the metals pre-manufactured on the step structures 205 to form eutectic layers 208. Alternatively, vacuum packaging may be performed through a vacuum reflow soldering device. In actual application, a vacuum packaging device may be flexibly selected.

According to the LED device 200 provided in this embodiment, the metal layers are pre-manufactured on the step structures 205, and the solder layers are pre-manufactured on the optical assembly 203, which are packaged in the vacuum soldering system, to realize a vacuum environment in the device, so as to prevent the device from exploding as a result of air expansion inside the device during use. Moreover, the uniformity, the shape, and the thickness of the eutectic layers 208 formed by the combination of the metal layers and the solder layers may be controlled through the pre-manufactured solder layers, which realizes a more desirable light emitting effect of LED device 200.

FIG. 7 is a schematic cross-sectional structural diagram of another LED device (III) according to Embodiment II. As shown in FIG. 7, this embodiment provides an LED device 210, including a concave support 211, a light source 212, and an optical assembly 213. Symmetrical step structures 215 are arranged on inner sides of two protruding ends of the concave support 211. A metal layer is pre-manufactured on each of the step structures 215. The optical assembly 213 is fitted to the step structures 215.

In some embodiments, the step structures 215 are double-L-shaped step structures. It should be understood that specific structural forms of the step structures are not limited to the double-L-shaped step structures in this embodiment, and may be flexibly arranged according to an actual need.

FIG. 8 is a schematic cross-sectional structural diagram of another LED device (IV) according to Embodiment II. This embodiment provides an LED device 220, including a concave support 221, a light source 222, and an optical assembly 223, as shown in FIG. 8. Symmetrical step structures 225 are arranged on inner sides of two protruding ends of the concave support 221. Each of the step structures 225 is a slant step structure, and the optical assembly 243 is a quartz lens. The quartz lens may be an adaptive lens that achieves an emitted light type with a half-angle width of 210 degrees, 30 degrees, 60 degrees, or other angles. An LED device 240 provided in some embodiments includes a concave support 241, an LED chip 242, and an optical assembly 243. The LED chip 242 is fixed to an inner bottom of the concave support 241. Electrodes of the LED chip 242 are connected to electrodes of the concave support 241. Symmetrical step structures 245 are arranged on inner sides of two protruding ends of the concave support 241. FIG. 11 is an LED device packaging flowchart according to Embodiment II. As shown in FIG. 11, this embodiment provides an LED device packaging process, including the following steps:

Step S21: Designing a concave support structure, including: designing a concave base plate structure and arranging symmetrical step structures on inner sides of two protruding ends of the concave support according to product requirements.

Step S22: Pre-manufacturing a metal layer on each of the step structures, where the metal layer is generally made of Au or Ag, and a thickness of the metal layer is generally in a range of 10-100 μm.

Step S23: Fixing and mounting an LED chip, including: fixing the LED chip to an inner bottom of the concave support with silver glue or silicone resin glue, soldering the LED chip with metal wires, and connecting electrodes of the LED chip to electrodes of the concave support.

Step S24: Placing an optical assembly on the step structures of the concave support, including: placing the optical assembly having pre-manufactured solder layers thereon on the corresponding steps on the concave support, where regions of solders are less than or equal to the step regions of the concave support, so as to prevent the light emitting effect of the product from being affected as a result of the solders diffusing to regions other than the step structures of the concave support after melting.

Step S25: Performing vacuum soldering on the LED device, including: placing the LED device in step S24 in a vacuum soldering system; performing vacuumization, where since the optical assembly and the concave support are not combined at this time, air inside the LED device is completely pumped out in the vacuum environment, so that a vacuum state is realized inside the LED device; and heating the LED device, so that the solders pre-manufactured on the optical assembly are melted and combined with the pre-manufactured metal layers on the concave support step to form eutectic layers.

The LED device packaged in vacuum provided in some embodiments may be applied to a packaging structure of a non-visible LED device such as an infrared LED or an ultraviolet LED. The device packaged in vacuum provided in the embodiments may further include a light receiving chip, but the present invention is not limited thereto.

### Embodiment III

FIG. 12 is a schematic cross-sectional structural diagram of a light source assembly according to Embodiment III. Referring to FIG. 12, this embodiment provides a light source assembly 300. The light source assembly 300 includes a carrier plate 301, a light source 302, and an optical assembly. The optical assembly includes a collimator 303 and a dimming assembly 304. In some embodiments, the carrier plate 301 is a base plate, and the light source 302 may be but is not limited to a light emitting chip. The light source 302 is arranged on the carrier plate 301, the collimator 303 is connected to the carrier plate 301, the dimming assembly 304 is mounted to the collimator 303, and the collimator 303 is configured to collimate light emitted by the light source 302 and cause the light to be incident onto the dimming assembly 304. The dimming assembly 304 includes a dimmer 3041. The dimmer 3041 is configured to adjust the light incident onto the dimming assembly 304 to light of a target chrominance for emission.

Specifically, a plurality of lines for series-parallel independent control are arranged on the base plate 301. As shown in FIG. 14, a plurality of light emitting chips 302 may be arranged on the base plate 301. The light emitting chips 302 are controlled separately through the plurality of lines for series-parallel independent control, so as to control a designated light emitting chip 302 to emit light as required. Based on the light source assembly 300, the light emitting chip 302 is soldered to the base plate 301 through solders such as solder paste. The connection between the collimator 303 and the base plate 301 may be realized in any feasible way such as adhesive connection, snap connection, or screw connection. As shown in FIG. 12, optionally, a fixing hole 3012 is arranged on the base plate 301, and a fixing portion 3035 configured to be fitted to the fixing hole 3012 is arranged on the collimator 303. The collimator 303 is fixedly connected to the base plate 301 through fitting and mounting of the fixing portion 3035 to the fixing hole 3012. The collimator 303 can be precisely positioned by adjusting a position of the fixing hole 3012. The dimming assembly 304 is connected to a side of the collimator 303 away from the base plate 301, and the collimator 303 is arranged around the light emitting chip 302. When the light emitting chip 302 emits light, the light is collimated on an inner surface of the collimator 303 to adjust an angle of the light, so that the light is vertically incident onto the dimming assembly 304, thereby making full use of the light. A dimmer 3041 is arranged on the dimming assembly 304. The dimmer 3041 is usually a nanometer material with unique optical characteristics, which can accurately and efficiently convert red, green, or blue light into white light for emission, thereby improving a color gamut of the light source assembly 300.

The light emitted by the light emitting chip 302 is collimated to the dimming assembly 304 through the arranged collimator 303, and then the dimming assembly 304 adjusts the light to the light of the target chrominance for emission. The dimming assembly 304 is arranged on a light outgoing side of the light emitting chip 302, so that a quantum dot film does not need to be arranged on the light guide plate, which reduces the costs.

### <Dimming Assembly>

FIG. 15 is a schematic structural diagram of a dimming assembly according to Embodiment III. Referring to FIG. 12 and FIG. 15, in some embodiments, the dimming assembly 304 further includes a light-transmitting member 3042 and a protective member 3043. The dimmer 3041, the light-transmitting member 3042, and the protective member 3043 are stacked in sequence. Specifically, the light-transmitting member 3042 includes two opposite surfaces, one of which is connected to the collimator 303, and the other is provided with a first groove. The dimmer 3041 is accommodated in the first groove and completely covers a bottom wall of the first groove, so that all light emitted from the light-transmitting member 3042 can pass through the dimmer 3041 for adjustment. Preferably, the light-transmitting member 3042 is a light-transmitting plate made of a polymethylmethacrylate (PMMA) material, which has a desirable light translucency and structural stability and high reliability. Optionally, the light-transmitting member 3042 is made of other materials that can achieve a light-transmitting function, and a structure of the light-transmitting member 3042 may be a light-transmitting film, a light-transmitting post, or the like. A surface of the light-transmitting member 3042 facing away from the dimmer 3041 is a light incident surface 3044, and a surface of the protective member 3043 facing away from the dimmer 3041 is a light outgoing surface 3045. The light emitted from the collimator 303 enters the dimmer 3041 through the light incident surface 3044, and is then emitted through the light outgoing surface 3045 after being adjusted to the light of the target chrominance by the dimmer 3041.

Specifically, the target chrominance is white, for example. When the light emitted by the light emitting chip 302 is red, blue, or green, the light emitted by the light emitting chip 302 is collimated through the collimator 303 to cause all the light to be incident onto the light-transmitting member 3042 perpendicular to the light incident surface 3044, so as to avoid a light loss caused by a light leakage. The light passes through the light-transmitting member 3042 and enters the dimmer 3041. The dimmer 3041 adjusts the red, green, or blue light to the light of the target color and causes the light to be incident onto the protective member 3043. The protective member 3043 can completely cover the dimmer 3041 to package the dimmer 3041 in the light-transmitting member 3042. In this embodiment, the protective member 3043 is completely accommodated in the first groove. In other embodiments, the protective member 3043 may be a structure with an area greater than that of the first groove to completely cover the dimmer 3041, so as to achieve isolation and protection of the dimmer 3041 and the light-transmitting member 3042. The protective member 3043 is transparent silica gel with characteristics such as a low moisture absorptivity, a low stress, and aging resistance, which can improve the reliability of the light source assembly 300. By arranging the dimming assembly 304 as a stacked three-layer structure including the light-transmitting member 3042, the dimmer 3041, and the protective member 3043 and packaging the dimmer 3041 and the protective member 3043 in the first groove arranged on the light-transmitting member 3042, desirable structural tightness is realized. The dimmer 3041 adjusts the light emitted by the light source to the light of the target chrominance for emission, so that a quantum dot film does not need to be arranged on the light guide plate, which reduces the difficulty of white balance adjustment of the light source assembly 300. Moreover, the separate arrangement of the dimmer 3041 and the light emitting chip 302 mitigates the attenuation of the dimmer 3041, thereby increasing the service life of the light source assembly 300.

In some embodiments, referring to FIG. 12, the dimmer 3041 may be quantum dot phosphor or phosphor. The quantum dot phosphor or the phosphor has unique optical properties. When stimulated by light, the quantum dot phosphor or the phosphor emits colored light. The color of light depends on a constituent material and a size and a shape of the quantum dot phosphor and the phosphor. For example, the constituent material of the quantum dot film may be one or a combination of two of red quantum dot phosphor, green quantum dot phosphor, and blue quantum dot phosphor. Generally, quantum dot phosphor with larger particles absorbs longer waves, and quantum dot phosphor with smaller particles absorbs shorter waves. For example, an 8-nanometer quantum film can absorb red color of a long wave and show blue color, and a 2-nanometer quantum film can absorb blue color of a short wave and shows red color. Similarly, a composition of the phosphor may be one or a combination of two of red phosphor, green phosphor, and blue phosphor. The above characteristic enables the quantum dot phosphor or the phosphor to change the color of light emitted from the dimming assembly 304. For example, the quantum dot phosphor can emit full-spectrum light when illuminated by a blue light source, so as to adjust the light for fine adjustment of the backlight, which greatly improves the color gamut performance and realizes a more distinct color.

In some embodiments, referring to FIG. 12, the light emitting chip 302 may be any one or two of a blue light chip, a green light chip, a red light chip, and a non-visible light chip, or may be a combination of the light emitting chips 302, and the light emitting chip 302 and the dimmer 3041 are configured to correspond to each other.

For example, the light of the target chrominance is white light. When the light emitting chip 302 is a monochrome chip, the light emitting chip 302 and the dimmer 3041 are configured to correspond to each other as follows: When the light emitting chip 302 is a blue light chip, the quantum dot phosphor or the phosphor of the dimmer 3041 is a combination of red and green, and the dimmer 3041 adjusts the blue light to white light for emission. When the light emitting chip 302 is a green light chip, the quantum dot phosphor or the phosphor of the dimmer 3041 is a combination of blue and red, and the dimmer 3041 adjusts the green light to white light for emission. When the light emitting chip 302 is a red light chip, the quantum dot phosphor or the phosphor of the dimmer 3041 is a combination of blue and green, and the dimmer 3041 adjusts the red light to white light for emission.

When the light emitting chip 302 is a combination of light sources of two colors, the light emitting chip 302 and the dimmer 3041 are configured to correspond to each other as follows: When the chip 302 is a combination of a blue light chip and a red light chip, the dimmer 3041 is green quantum dot phosphor or green phosphor. When the light emitting chip 302 is a combination of a red light chip and a green light chip, the dimmer 3041 is blue quantum dot phosphor or blue phosphor. When the light emitting chip 302 is a combination of a blue light chip and a green light chip, the dimmer 3041 is red quantum dot phosphor or red phosphor.

In other embodiments, referring to FIG. 12, the light emitting chip 302 is a white light chip. In this case, the dimmer 3041 does not need to be arranged on the dimming assembly 304, that is, the light emitted by the light emitting chip 302 does not need to be adjusted, and a quantum dot film or phosphor for light adjustment does not need to be arranged on the dimming assembly 304. Arranging the light emitting chip 302 and the dimmer 3041 to correspond to each other realizes diverse arrangements of the light emitting chip 302, which can satisfy different requirements. Optionally, the light emitting chip 302 is a flip-chip, which has characteristics of strong thermal conductivity, high reliability, and high power drive.

In some embodiments, referring to FIG. 12 and FIG. 15, a first fitting portion 3046 is arranged on an edge of the light-transmitting member 3042, and a second fitting portion 3031 is arranged on the collimator 303. The first fitting portion 3046 and the second fitting portion 3031 are fitted and connected to each other. In this embodiment, the first fitting portion 3046 is a step structure protruding downward, and the second fitting portion 3031 is a second groove arranged to correspond to the first fitting portion 3046, which is configured to accommodate the protrusion of the first fitting portion 3046. The first fitting portion 3046 and the second fitting portion 3031 are hermetically connected by using glue to seal the collimator 303 through the light-transmitting member 3042, thereby preventing a light loss caused by a light leakage. In other embodiments, the light-transmitting member 3042 and the collimator 303 may be packaged through other structures in other mounting ways, such as snap connection. The fitting and connection between the first fitting portion 3046 and the second fitting portion 3031 facilitate the precise mounting of the dimming assembly 304 and the collimator 303.

### <Collimator>

In some embodiments, referring to FIG. 12, the collimator 303 is a reflection cup. The reflection cup includes a cup body and a reflective surface 3032 defining a light source cavity. A lighting distance and a lighting area of a light spot may be controlled by reflecting light incident onto an inner wall of the collimator 303. The cup body of the reflection cup is usually a cup-shaped structure made of plastic, glass, or metal. The reflective surface 3032 is a metal coating on an inner wall of the cup. A coating layer of metal such as nickel or chromium is coated on the inner wall of the cup to realize the reflective function of light by the reflection cup. The light source cavity includes a light inlet 3033 and the light outlet 3034. The reflection cup is connected to the base plate 301. The light inlet 3033 is flush with the base plate 301, and the base plate 301 is hermetically connected to the light inlet 3033 to prevent a light leakage. The light emitting chip 302 is accommodated in the light source cavity and is located at the light inlet 3033, and the light-transmitting member 3042 is located at the light outlet 3034, and completely covers the light outlet 3034. The second fitting portion 3031 is arranged on the reflective surface 3032. The light emitted by the light emitting chip 302 propagates in the light source cavity. The light emitted by the light emitting chip 302 may include two parts. A first part of the light is directly incident onto the light-transmitting member 3042 through the light inlet 3033, and the other part of the light that is not directly incident onto the light-transmitting member 3042 is incident onto the reflective surface 3032 and is reflected by the reflective surface 3032 for collimation and then incident onto the light-transmitting member 3042. By arranging the reflective surface 3032 around the light emitting chip 302, the light emitted by the light emitting chip 302 can be fully collimated and incident onto the light-transmitting member 3042, which avoids a light loss and improves the light utilization.

In other embodiments, the collimator 303 is a total internal reflection lens. The light emitted by the light emitting chip 302 is incident onto the total internal reflection lens. The total internal reflection lens reflects all the light to cause the light to be incident onto the dimming assembly 304, so as to improve the light utilization rate and save resources.

In some embodiments, referring to FIG. 12, a reflective layer (or a shield layer) 3011 is arranged at a position of the base plate 301 corresponding to the light inlet 3033, and the reflective layer (or the shield layer) 3011 is connected to the reflective surface 3032. In this embodiment, the reflective layer (or the shield layer) 3011 adopts a black adhesive tape, which can not only realize bonding and fixing, but also realize shielding to avoid a light leakage from a gap at a joint of the base plate 301 and the light inlet 3033. In other embodiments, other materials with reflective or shielding properties, such as a metal coating with a reflective effect may be used.

### <Light Source>

FIG. 21 is a schematic structural diagram of a light source according to Embodiments I-IV. Referring to FIG. 21, the light source may be arranged on the carrier plate based on the light source assembly. In some embodiments, the light source may be an LED chip 500, including a chip body and a substrate 501. A semiconductor layer 502 is arranged on the LED chip body. The semiconductor layer 502 includes an N-type semiconductor layer and a P-type semiconductor layer. A first electrode layer 503 is arranged on a side of the semiconductor layer 502 facing away from the substrate 501. A second electrode layer 504 is arranged on a side of the first electrode layer 503 facing away from the substrate 501. The second electrode layer 504 completely covers the first electrode layer 503. A third electrode layer 505 is arranged on a side of the second electrode layer 504 facing away from the first electrode layer 503. The second electrode layer 504 reacts with a target solder that permeates the third electrode layer 505 to form a soldering structure. According to the LED chip 500 in this embodiment, the second electrode layer 504 is arranged between the first electrode layer 503 and the third electrode layer 505, and the second electrode layer 504 can react with the target solder with which the third electrode layer 505 is doped and that permeates the third electrode layer, so that the third electrode layer 505 reacts with the target solder and the second electrode layer 504 reacts with the target solder respectively to obtain a soldering layer, thereby forming a stable soldering structure between the second electrode layer 504 and the third electrode layer 505. Therefore, the soldering reliability is enhanced without increasing a thickness of the third electrode layer 505, and the problem of low soldering reliability as a result of possible voids in the soldering layer formed by the LED electrodes and the solder is prevented.

In some embodiments, a material of the substrate 501 includes but is not limited to one or more of sapphire aluminum oxide, silicon carbide, silicon, gallium nitride, gallium arsenide, gallium phosphide, indium phosphide, and aluminum gallium indium phosphate.

In some embodiments, the semiconductor layer 502 is a gallium nitride based semiconductor layer, that is, the N-type semiconductor layer and the P-type semiconductor layer are both the gallium nitride based semiconductor layer. It should be understood that the semiconductor layer 502 in this embodiment of this application may alternatively be made of other materials. This is not specifically limited in this application.

It should be understood that the LED chip 500 further includes structural layers such as a quantum well layer and a conductive layer, which are not described in detail herein.

In some embodiments, the LED chip 500 further includes a reflective layer 506 arranged between the semiconductor layer 502 and the first electrode layer 503. FIG. 22 is a schematic structural diagram of a light source (II) according to Embodiments I-IV. As shown in FIG. 22, it should be understood that the reflective layer 506 is formed on a side surface of the semiconductor layer 502 away from the substrate 501 through a deposition process. The reflective layer 506 is made of one or more of ITO, Ag, Au, Al, Cr, Ni, and Ti. Light emitted by the LED chip 500 from the quantum well layer (not shown in the figure) is partly emitted from a side of the substrate 501 directly and partly emitted from a side facing away from the substrate 501, which reduces the light extraction efficiency. Currently, in the prior art, a distributed bragg reflector (DBR) layer is arranged on the side facing away from the substrate 501 to reflect the light on the side facing away from the substrate 501. However, a device for forming the DBR layer is expensive and the process is complex. In some examples, the LED chip 500 reflects the light on the side facing away from the substrate 501 back to the side of the substrate 501 through the reflective layer 506 arranged on the surface of the semiconductor layer 502, thereby improving the light outgoing efficiency of the LED chip 500 and the brightness of the LED chip 500.

In some embodiments, a filler metal layer is deposited on the side surface of the semiconductor layer 502 away from the substrate 501 through an electron beam evaporation, magnetron sputtering, electroplating, or chemical plating process to form the first electrode layer 503. When the reflective layer 506 is arranged on the side surface of the semiconductor layer 502 away from the substrate 501 of the LED chip, a filler metal layer is deposited on a side surface of the reflective layer 506 away from the substrate 501 to form the first electrode layer 503. A thickness of the first electrode layer 503 is in a range of 0.2 μm to 0.4 μm. A material of the first electrode layer 503 includes but is not limited to one or a combination of Cr, Ti, Al, Ni, and Pt for forming the first electrode layer 503. Preferably, the thickness of the first electrode layer 503 is 0.2 μm.

In some embodiments, a filler metal layer is deposited on a side of the first electrode layer 503 away from the substrate 501 through the electron beam evaporation, magnetron sputtering, electroplating, or chemical plating process to form a second electrode layer 504. A thickness of the second electrode layer 504 is in a range of 0.4 μm to 0.6 μm. Preferably, the thickness of the second electrode layer 504 is 0.4 μm. It should be noted that the target solder is a tin-containing solder, and the second electrode layer 504 is a metal electrode layer that can react with the tin-containing solder. A material of the target solder includes but is not limited to one or more of mixtures such as tin, tin silver copper, tin bismuth copper, and lead tin. A material of the second electrode layer 504 includes but is not limited to one of metals that can form a stable alloy structure with the target solder, such as Cr, Ti, Ni, Pt, and CU. For example, the target solder is solder paste, and the second electrode layer 504 is a copper (Cu) metal layer. In this case, the second electrode layer 504 and the target solder that permeates the third electrode layer 505 form a stable Cu6Sn5 soldering layer. Therefore, the soldering stability is enhanced without increasing a thickness of the third electrode layer 505, thereby improving the long-term operation reliability of the LED chip 500. Moreover, since the second electrode layer 504 completely covers the first electrode layer 503, the conductivity is prevented from being affected by permeation of the target solder into the first electrode layer 503. In addition, since the third electrode layer 505 is not changed, the conductivity of the third electrode layer 505 is prevented from being affected, thereby ensuring the conductivity efficiency of the third electrode layer 505.

In some embodiments, a filler metal layer is deposited on a side of the second electrode layer 504 away from the substrate 501 through the electron beam evaporation, magnetron sputtering, electroplating, or chemical plating process to form a third electrode layer 505. A thickness of the third electrode layer 505 is in a range of 0.5 μm to 0.7 μm. A material of the third electrode layer 505 includes but is not limited to one or a combination of AU and Pt for forming the third electrode layer 505. Preferably, the thickness of the third electrode layer 505 is 0.5 μm.

A chip provided in some embodiments includes a substrate 501 and a chip body arranged on a side of the substrate 501. A semiconductor layer 502 is arranged on the chip body. The semiconductor layer 502 includes an N-type semiconductor layer and a P-type semiconductor layer. A first electrode layer 503 is arranged on a side of the semiconductor layer 502 facing away from the substrate 501. A second electrode layer 504 is arranged on a side of the first electrode layer 503 facing away from the substrate 501. The second electrode layer 504 completely covers the first electrode layer 503. A third electrode layer 505 is arranged on a side of the second electrode layer 504 facing away from the first electrode layer 503. The second electrode layer 504 reacts with a target solder that permeates the third electrode layer 505 to form a soldering structure. Since the second electrode layer 504 that can react with the target solder that permeates the third electrode layer 505 is arranged between the first electrode layer 503 and the third electrode layer 505, not only the third electrode layer 505 reacts with the target solder to obtain a soldering layer, but also the target solder that permeates the third electrode layer 505 reacts with the second electrode layer 504 to obtain a stable soldering layer. Therefore, the target solder reacts with the second electrode layer 504 and the third electrode layer 505 respectively to form a stable soldering structure without increasing the thickness of the third electrode layer 505. In this way, the soldering reliability is enhanced, and the problem of low soldering reliability as a result of possible voids in the soldering layer formed by the LED electrodes and the solder is prevented.

FIG. 23 is a schematic flowchart of a light source manufacturing method according to Embodiment V. As shown in FIG. 23, the method includes but is not limited to the following steps:

Step S41: Forming a chip on a side of a substrate. In some examples of this embodiment, a material of the substrate includes but is not limited to one or more of sapphire aluminum oxide, silicon carbide, silicon, gallium nitride, gallium arsenide, gallium phosphide, indium phosphide, and aluminum gallium indium phosphate. The chip was grown on the substrate by using a metal organic chemical vapor deposition (MOCVD) device. For example, an N-type semiconductor layer, a quantum well layer, and a P-type semiconductor layer are successively and epitaxially grown on the substrate through the MOCVD device, or the P-type semiconductor layer, the quantum well layer, and the N-type semiconductor layer are successively and epitaxially grown on the substrate through the MOCVD device. The P-type semiconductor layer and the N-type semiconductor layer are collectively referred to as a semiconductor layer.

Step S42: Arranging a first electrode layer on a side of the semiconductor layer facing away from the substrate. In some examples of this embodiment, the first electrode layer is arranged on the side of the semiconductor layer facing away from the substrate. For example, when the N-type semiconductor layer, the quantum well layer, and the P-type semiconductor layer have been successively grown on the substrate, a part of the quantum well layer and the P-type semiconductor layer is peeled off through an etching process, to expose a part of the N-type semiconductor layer, and a filler metal layer is deposited on side surfaces of the P-type semiconductor layer and the exposed N-type semiconductor layer away from the substrate through the electron beam evaporation, magnetron sputtering, electroplating, or chemical plating process, to form the first electrode layer. Alternatively, when the P-type semiconductor layer, the quantum well layer, and the N-type semiconductor layer have been successively grown on the substrate, a part of the quantum well layer and the N-type semiconductor layer is peeled off through an etching process, to expose a part of the P-type semiconductor layer, and a filler metal layer is deposited on side surfaces of the N-type semiconductor layer and the exposed P-type semiconductor layer away from the substrate, to form the first electrode layer. A thickness of the first electrode layer is in a range of 0.2 μm to 0.4 μm, and a material of the first electrode layer includes but is not limited to one or a combination of Cr, Ti, Al, Ni, and Pt.

It should be understood that the etching process provided in this embodiment of this application may be either a dry etching process or a wet etching process. This is not specifically limited in this application, and may be selected according to actual application.

It should be understood that in some embodiments, arranging the first electrode layer on the side of the semiconductor layer facing away from the substrate includes: arranging a reflective layer on the side of the semiconductor layer facing away from the substrate, and arranging the first electrode layer on a side of the reflective layer facing away from the semiconductor layer. For example, a part of the N-type semiconductor layer is exposed through the etching process, and then the reflective layer is formed on side surfaces of the P-type semiconductor layer and the exposed part of the N-type semiconductor layer away from the substrate through the deposition process. Alternatively, a part of the P-type semiconductor layer is exposed through the etching process, and then the reflective layer is formed on side surfaces of the N-type semiconductor layer and the exposed part of the P-type semiconductor layer away from the substrate through the deposition process. The reflective layer is made of one or more of ITO, Ag, Au, Al, Cr, Ni, and Ti. It should be understood that at this time, a filler metal layer is deposited on the surface of the reflective layer away from the substrate to form the first electrode layer.

Step S43: Arranging a second electrode layer on a side of the first electrode layer facing away from the substrate, where the second electrode layer completely covers the first electrode layer. In some examples of this embodiment, a filler metal layer is deposited on the side of the first electrode layer away from the substrate through the electron beam evaporation, magnetron sputtering, electroplating, or chemical plating process to form the second electrode layer. A thickness of the second electrode layer is in a range of 0.4 μm to 0.6 μm. It should be noted that in some examples, the target solder is a tin-containing solder, and the second electrode layer is a metal electrode layer that can react with the tin-containing solder. For example, the target solder is solder paste, and the second electrode layer is a copper (Cu) metal layer. In this case, the second electrode layer and the target solder that permeates a third electrode layer form a stable Sn5Cu6 soldering layer. Therefore, the soldering stability is enhanced without increasing a thickness of the third electrode layer, thereby improving the long-term operation reliability of the LED chip. Moreover, since the second electrode layer completely covers the first electrode layer, the conductivity is prevented from being affected by permeation of the target solder into the first electrode layer.

Step S44: Arranging a third electrode layer on a side of the second electrode layer facing away from the first electrode layer. In some examples of this embodiment, a filler metal layer is deposited on the side of the second electrode layer away from the substrate through the electron beam evaporation, magnetron sputtering, electroplating, or chemical plating process to form the third electrode layer. A thickness of the third electrode layer is in a range of 0.5 μm to 0.7 μm. A material of the third electrode layer includes but is not limited to a metal such as AU or an alloy combination of the metal for forming the third electrode layer.

In the LED chip manufacturing method provided in some embodiments, the chip is formed on the side of the substrate, where the chip includes the semiconductor layer, and the semiconductor layer includes the N-type semiconductor layer and the P-type semiconductor layer, the first electrode layer is arranged on the side of the semiconductor layer facing away from the substrate, the second electrode layer is arranged on the side of the first electrode layer facing away from the substrate, where the second electrode layer completely covers the first electrode layer, and the third electrode layer is arranged on the side of the second electrode layer facing away from the first electrode layer. In the chip manufactured by this method, since the second electrode layer that can react with the target solder that permeates the third electrode layer is arranged between the first electrode layer and the third electrode layer, not only the third electrode layer reacts with the target solder to obtain a soldering layer, but also the target solder that permeates the third electrode layer reacts with the second electrode layer to obtain a stable soldering layer. Therefore, the target solder reacts with the second electrode layer and the third electrode layer respectively to form a stable soldering structure without increasing the thickness of the third electrode layer. In this way, the soldering reliability is enhanced, and the problem of low soldering reliability as a result of possible voids in the soldering layer formed by the LED electrodes and the solder is prevented.

FIG. 24 is a schematic structural diagram of a light source (III) according to Embodiments I-IV. Referring to FIG. 24, the LED chip 500 includes but is not limited to a substrate 501; an N-type semiconductor layer 5021, a quantum well layer 507, and a P-type semiconductor layer 5022 successively and epitaxially grown on the substrate 501; and a reflective layer 506 formed on side surfaces of the P-type semiconductor layer 5022 and an exposed N-type semiconductor layer 5021 away from a side surface of the substrate 501 through a deposition process, where the exposed N-type semiconductor layer is obtained by exposing a part of the N-type semiconductor layer 5021 by peeling off a part of the quantum well layer 507 and the P-type semiconductor layer 5022 through an etching process.

A material of the substrate 501 is a silicon-free structure formed by titanium dioxide, the N-type semiconductor layer 5021 and the P-type semiconductor layer 5022 are gallium nitride based semiconductor layers, and the reflective layer 506 is made of ITO.

In some embodiments, the LED chip 500 further includes a first electrode layer 503 formed by depositing filler Cr on a surface of the reflective layer 506 away from the substrate 501 through an electroplating process. A thickness of the first electrode layer 503 is 0.2 μm. After the first electrode layer 503 is formed, Cu is deposited on a surface of the first electrode layer 503 facing away from the side surface of the semiconductor to form a second electrode layer 504. A thickness of the second electrode layer 504 is 0.4 μm. After the second electrode layer 504 is formed, an Au layer is deposited on an upper surface of the second electrode layer 504 to form a third electrode layer 505. A thickness of the third electrode layer 505 is 0.5 μm.

In some embodiments, the LED chip 500 includes a substrate 501; an N-type semiconductor layer 5021, a quantum well layer 507, and a P-type semiconductor layer 5022 successively and epitaxially grown on the substrate 501; and a reflective layer 506. A first electrode layer 503 is arranged on a side of the semiconductor layer 502 facing away from the substrate 501. A second electrode layer 504 is arranged on a side of the first electrode layer 503 facing away from the substrate 501, and the second electrode layer 504 completely covers the first electrode layer 503. A third electrode layer 505 is arranged on a side of the second electrode layer 504 facing away from the first electrode layer 503. Since the second electrode layer 504 that can react with the target solder that permeates the third electrode layer 505 is arranged between the first electrode layer 503 and the third electrode layer 505, not only the third electrode layer 505 reacts with the target solder to obtain a soldering layer, but also the target solder that permeates the third electrode layer 505 reacts with the second electrode layer 504 to obtain a stable soldering layer. Therefore, the target solder reacts with the second electrode layer 504 and the third electrode layer 505 respectively to form a stable soldering structure without increasing the thickness of the third electrode layer 505. In this way, the soldering reliability is enhanced, and the problem of low soldering reliability as a result of possible voids in the soldering layer formed by the LED electrodes and the solder is prevented.

It should be understood that a surface of each of the above carrier board, circuit board, base plate, or support is not limited to a plane, and may alternatively be a non-planar or curved surface with a concave or convex portion.

### <Backlight Module>

FIG. 13 is a schematic cross-sectional structural diagram of a backlight module to which the light source assembly is applicable according to Embodiments I-III. Referring to FIG. 13, the above light source assembly 300 is applicable to a backlight module 310. The backlight module 310 includes an edge-lit backlight module and a direct-lit backlight module. The carrier plate includes a base plate 301 and a support 305. The backlight module 310 further includes a light guide plate 306. The base plate 301 and the light guide plate 306 are both mounted to the support 305. The light guide plate 306 includes a side surface 3061 and a first surface 3062 and a second surface 3063 opposite to each other. The first surface 3062 is connected to the support 305. The side surface 3061 is connected to the first surface 3062 and the second surface 3063. The dimming assembly 304 is opposite to the side surface 3061. The light emitted by the dimming assembly 304 is incident onto the light guide plate 306 through the side surface 3061 and emitted through the second surface 3063.

Specifically, a reflective layer 307 is further arranged between the first surface 3062 and the support 305. The reflective layer 307 is configured to reflect the light from the dimming assembly 304 incident onto the first surface 3062 of the light guide plate 306 through the side surface 3061, and then the light is incident onto the second surface 3063 through a light guide effect of the light guide plate 306. A brightening layer 308 is arranged on the second surface 3063 to aggregate the scattered light emitted from the second surface 3063, thereby improving the brightness and enhancing the display effect. By arranging the dimming assembly 304 on the side surface 3061 of the light guide plate 306, the edge-lit backlight structure is realized, which reduces a thickness of the backlight module 310, thereby realizing a light and thin product. In addition, since a quantum dot film layer on the light guide plate 306 is omitted, the costs are reduced.

In some embodiments, FIG. 16 is a schematic cross-sectional structural diagram of a backlight module (II) according to Embodiment III. Referring to FIG. 16, the light outgoing surface 3045 of the protective member 3043 is a convex surface. Specifically, a transparent coating layer with a high refractive index, such LED silica gel or epoxy resin may be sprayed onto the light outgoing surface 3045 of the protective member 3043 to realize the convex light outgoing surface 3045, thereby aggregating the light. When the light outgoing surface 3045 is a convex surface, the light collimated by the collimator 303 is vertically incident onto the protective member 3043, and is refracted by the light outgoing surface 3045 and then aggregated directionally, and is then incident onto the light guide plate 306, so as to realizing aggregation of the light, thereby realizing coupling of the light and the side surface 3061 of the light guide plate 306 more effectively. By arranging the light outgoing surface 3045 of the protective member 3043 as the convex surface, the light source assembly 300 is applicable to more scenarios, and a light leakage from an edge of the side surface 3061 of the light guide plate 306 is avoided. It may be understood that, referring to FIG. 13, the light outgoing surface 3045 of the protective member 3043 may alternatively be a plane.

In some embodiments, the above light source assembly, the LED device applied to the light source assembly, and the light source structure of the light source assembly are all applicable to the backlight module 310.

### <Display Device>

In some embodiments, a display device is provided. The display device may be any electronic device with a liquid crystal display function, such as a television screen, a computer display, or a wearable device. FIG. 17 is a schematic structural diagram of a display device to which the light source assembly is applicable according to Embodiment III. As shown in FIG. 17, the display device includes the backlight module in any of the above embodiments, and the display device further includes a display panel 309. The display panel 309 is arranged opposite to the light guide plate 306 of the backlight module 310. Since the display device adopts the backlight module 310 in any of the above embodiments, the display device provided in this embodiment also requires low manufacturing costs.

FIG. 18 is a schematic structural diagram of a touch screen structure module of the display device to which the light source assembly is applicable according to some Embodiments I-III. FIG. 18 shows the touch screen structure module of the display device to which the light source assembly is applicable. The display device includes a touch screen structure module 400. The touch screen structure module 400 includes a carrier plate and a light source. In some embodiments, the carrier plate includes a base plate 401. The base plate 401 is divided into a first region 402 and a second region 403 surrounding the first region 402. In some embodiments, the light source is, for example, a light emitting chip and/or a light receiving chip. The above chip is a blue light flip-chip 404, a non-visible light emitting chip (for example, an infrared emitting chip 405), or a light receiving chip (for example, an infrared receiving chip 406). A plurality of blue light flip-chips 404 are arranged in the first region 402. A plurality of infrared emitting chips 405 located on two adjacent sides of the first region 402 and a plurality of infrared receiving chips 406 located on the other two adjacent sides of the first region 402 are arranged in the second region 403. The plurality of infrared emitting chips 405 are in a one-to-one correspondence with the plurality of infrared receiving chips 406.

In some embodiments, micron-level blue light flip-chips 404 are arranged in the first region 402 of the base plate 401 to form a backlight module, and an optical distance OD of the backlight module is in a range of 0-1 mm. The second region 403 of the base plate 401 is a surrounding region of the first region 402. Infrared flip-chips (including infrared emitting chips 405 and an infrared receiving chips 406) are arranged in the second region 403 to form an emitting/receiving module. As an example, as shown in FIG. 18, the infrared emitting chips 405 are arranged on the left of and above the first region 402, and the infrared receiving chips 406 are arranged on the right of and below the first region 402. The infrared emitting chips 405 and the infrared receiving chips 406 are in a one-to-one correspondence. As another example, the infrared emitting chips 405 are arranged on the left of and below the first region 402, and the infrared receiving chips 406 are arranged on the right of and above the first region 402. It may be understood that positions of the infrared emitting chips 405 and the infrared receiving chips 406 in the second region 403 may be flexibly selected, as long as the infrared emitting chips 405 are located on the two adjacent sides of the first region 402, and the infrared receiving chips 406 are located on the other two adjacent sides of the first region 402.

In the above touch screen structure module 400, the blue light flip-chips 404, the infrared emitting chips 405, and the infrared emitting chips 405 are placed on the same base plate 401, that is, the infrared flip-chips (including the infrared emitting chips 405 and the infrared receiving chips 406) are arranged inside the backlight module, so that the overall module thickness is the thickness of the backlight module, thereby realizing a thin touch screen structure module 400.

In some embodiments, based on the light source assembly, solder paste is arranged on the base plate 401. The plurality of blue light flip-chips 404, the plurality of infrared emitting chips 405, and the plurality of infrared receiving chips 406 are bonded to the base plate 401 through the solder paste. It may be understood that the solder paste may be placed on a pad of the base plate 401 through printing. During subsequent fixing of various types of chips to the base plate 401, electrodes of the blue light flip-chips 404 or the infrared emitting chips 405 or the infrared receiving chips 406 may be attached to the solder paste on the base plate 401. Then the solder paste is melted through reflow soldering, so that the chip electrodes can be bonded to the pad of the base plate 401.

In some embodiments, a transparent protective adhesive layer is arranged on the base plate 401. Optionally, the transparent protective adhesive layer is a silica gel layer. Optionally, a thickness range of the transparent protective adhesive layer is in a range of 10-100 μm.

It may be understood that the surface of the base plate 401 may be packaged with a layer of transparent protective adhesive to protect the chip on the base plate 401. The transparent protective adhesive may be silica gel. A thickness of transparent protective adhesive includes but is not limited to 10 μm, 20 μm, 50 μm, and 100 μm. In other words, a top surface of the transparent protective adhesive may be higher than an upper surface of the chip, or may be flush with the upper surface of the chip, or may be lower than the upper surface of the chip, as along as the transparent protective adhesive can wrap and protect the chip.

### <Touch Screen Structure Module>

In some embodiments, a display device is further provided. The display device includes the touch screen structure module shown in any of the above embodiments. The display device described in this embodiment includes a display panel and the touch screen structure module arranged opposite to each other. The display panel displays images through backlight emitted by the touch screen structure module. In a specific application scenario, when a user touches the screen with a finger, a horizontal infrared ray and a vertical infrared ray passing through the position are shielded, so that a coordinate position of the touch point on the screen may be determined. Any non-transparent object can change the infrared ray on a contact to realize a touch operation.

In some embodiments, an electronic device is further provided. The electronic device includes the display device described in the above embodiment. In some embodiments, the electronic device may be electronic devices with a display function such as a mobile phone, a tablet computer, or a wearable device. The electronic device adopts the touch screen structure module described in the above embodiment, which is thin and satisfies the demand for a light and thin electronic device.

In some embodiments, a method for manufacturing a touch screen structure module is further provided. FIG. 19 is a flowchart of a method for manufacturing the touch screen structure module of the display device according to Embodiment IV, and FIG. 20 is a schematic flowchart of another method for manufacturing the touch screen structure module of the display device according to Embodiment IV. As shown in FIG. 19 and FIG. 20, the method includes the following steps:

Step S31: Providing a base plate, and arranging a plurality of blue light flip-chips in a first region of the base plate.

Step S32: Arranging a plurality of infrared emitting chips in a second region of the base plate on two adjacent sides of the first region, and arranging a plurality of infrared receiving chips in a one-to-one correspondence with the plurality of infrared emitting chips in the second region of the base plate on the other two adjacent sides of the first region.

It should be noted that before S31, the method includes S30: arranging solder paste on the base plate.

Step S31 includes step S311: placing a plurality of blue light flip-chips on the solder paste of the base plate in the first region of the base plate.

Step S32 includes step S321: placing the plurality of infrared emitting chips on the solder paste of the base plate in the second region of the base plate on the two adjacent sides of the first region, and placing the plurality of infrared receiving chips in a one-to-one correspondence with the plurality of infrared emitting chips on the solder paste of the base plate in the second region of the base plate on the other two adjacent sides of the first region.

After step S32, the method includes:

Step S33: Melting the solder paste through reflow soldering so that the plurality of blue light flip-chips, the plurality of infrared emitting chips, and the plurality of infrared receiving chips are bonded to the base plate.

It should be noted that the step S32 further includes:

Step S34: Arranging a transparent protective adhesive layer on the base plate.

In this embodiment, the present invention is further illustrated by using a manufacturing process of the touch screen structure module of the display device. The method includes: (1) attaching solder paste to the base plate through printing; (2) successively arranging blue light flip-chips and infrared flip-chips on the solder paste; (3) melting the solder paste through reflow soldering to bond chip electrodes to a pad on the base plate; and (4) packaging the surface of the base plate with a layer of transparent protective adhesive such as silica gel through molding to protect the chip on the base plate.

In some embodiments, the blue light flip-chips and the infrared flip-chips may be directly bonded to the base plate in the present invention. A thickness of each of the infrared flip-chips is at least 0.1 mm. The thickness of the touch screen structure module is the thickness of the backlight module, which is greatly reduced compared with the thickness of the existing touch screen structure module, thereby realizing a thin touch screen structure module.

In the touch screen structure module of the display device in this embodiment, the blue light flip-chips, the infrared emitting chips, and the infrared emitting chips are placed on the same circuit board; that is, the infrared flip-chips are arranged inside the backlight module, so that the overall module thickness is the thickness of the backlight module, thereby realizing a thin touch screen structure module.

It should be understood that the light source assembly is applicable to various fields of light emission. In addition to the application of the light source assembly to the backlight module and thereby to the display backlight field (for example, backlight modules of terminals such as TVs, displays, or mobile phones) as shown above, application to the key backlight field, the photography field, the household lighting field, the medical lighting field, the decoration field, the automobile field, the transportation field, and the like is also feasible. When applied to the key backlight field, the light source assembly may be used as a key backlight source for devices with keys such as mobile phones, calculators, or keyboards. When applied to the photography field, the light source assembly may be manufactured into a camera flash. When applied to the household lighting field, the light source assembly may be manufactured into a floor lamp, a table lamp, a lighting lamp, a ceiling lamp, a down lamp, or a spot lamp. When applied to medical lighting field, the light source assembly may be manufactured into a surgical lamp, a low electromagnetic lamp, or the like. When applied to the decoration field, the light source assembly may be manufactured into various decorative lamps, such as various colored lamps, landscape lamps, or advertising lamps. When applied to the automobile field, the light source assembly may be manufactured into an automobile lamp, an automobile indicator lamp, or the like. When applied to the transportation field, the light source assembly may be manufactured into various traffic lamps and street lamps. The light source assembly may be further applied to touch modules and display devices. The above application is merely a part of the examples in this embodiment. It should be understood that the application of the light source assembly is not limited to the above examples.

It should be understood that the terms “first”, “second”, “third”, “up”, “down”, “left”, “right”, “front”, and “back” used in the description are used to mark and explain the relationships between various technical features in each embodiment, and do not necessarily have the meaning of limiting the order, hierarchy, and front and back or spatial orientation (for example, a spatial location, a temporal sequence, and a step sequence).

1. A light source assembly, comprising:
a carrier plate; and
a plurality of light sources, arranged above the carrier plate in an array.

2. The light source assembly according to claim 1, further comprising:
a collimator, connected to the carrier plate; and
a dimming assembly, mounted to the collimator, wherein
the collimator is configured to collimate light emitted by the light sources and cause the light to be incident onto the dimming assembly; and
the dimming assembly comprises a dimmer configured to adjust the light incident onto the dimming assembly to light of a target chrominance for emission.

3. The light source assembly according to claim 2, wherein the dimming assembly further comprises a light-transmitting member and a protective member, the light-transmitting member, the dimmer, and the protective member are stacked in sequence, a surface of the light-transmitting member facing away from the dimmer is a light incident surface, a surface of the protective member facing away from the dimmer is a light outgoing surface, and light emitted through the collimator enters the dimmer through the light incident surface and is adjusted to the target chrominance by the dimmer and then emitted through the light outgoing surface.

4. The light source assembly according to claim 2, wherein the dimmer comprises quantum dot phosphor or phosphor.

5. The light source assembly according to claim 1, wherein the carrier plate comprises a concave support, a step structure is arranged on an inner side of each of two protruding ends of the concave support, and a metal layer is arranged on each of the step structures; and
an optical assembly, fitted to the step structures, wherein a solder layer is arranged at a position of each of two ends of the optical assembly fitted to the step structures;
the light sources are fixed to an inner bottom of the concave support, and electrodes of the light sources are connected to electrodes of the concave support through metal wires; and
the concave support and the optical assembly are sealed to form a sealed vacuum space, and each of the metal layer and each of the solder layer together form a eutectic layer.

6. The light source assembly according to claim 5, wherein the optical assembly comprises any one or a combination of the collimator, the dimming assembly, a diffractive optical element (DOE), a diffuser, a glass plate, and a lens.

7. The light source assembly according to claim 1, wherein the carrier plate further comprises a circuit board, and the circuit board comprises:
a plurality of pads, configured for soldering a chip, wherein an insulation portion is arranged around the pads;
a solder mask window, exposing a part of the pads and extending to expose a part of the insulation portion; and
a solder mask layer, arranged on a surface of the circuit board except for the solder mask window.

8. The light source assembly according to claim 7, wherein the pads of the circuit board comprise a positive pad and a negative pad, a separation region is arranged between the positive pad and the negative pad to separate and insulate the positive pad from the negative pad, and at least one bent portion is arranged in the separation region.

9. The light source assembly according to claim 7, wherein the circuit board further comprises a protective layer covering a surface on a side of the solder mask layer facing away from the circuit board.

10. The light source assembly according to claim 1, wherein each of the light sources is an LED chip, and the LED chip comprises:
a chip body, wherein a semiconductor layer is arranged on the chip body, and the semiconductor layer comprises an N-type semiconductor layer and a P-type semiconductor layer; and
a substrate, arranged on a side of the chip body, wherein
a soldering structure is arranged on a side of the semiconductor layer facing away from the substrate; and
the soldering structure comprises:
a first electrode layer, wherein
a second electrode layer is arranged on a side of the first electrode layer facing away from the substrate, and the second electrode layer completely covers the first electrode layer; and
a third electrode layer is arranged on a side of the second electrode layer facing away from the first electrode layer, and the second electrode layer reacts with a target solder with which the third electrode layer is doped and that permeates the third electrode layer.

11. The light source assembly according to claim 1, wherein the carrier plate comprises a circuit board, a base plate, or a support.

12. A backlight module, comprising:
the light source assembly according to claim 1; and
a light guide plate, mounted to the carrier plate, wherein
light emitted by the light sources is incident on the light guide plate and then emitted through the light guide plate.

13. A display device, comprising a display panel and the backlight module according to claim 12.

14. The display device according to claim 13, wherein the light source assembly further comprises:
a plurality of non-visible light emitting chips and a plurality of light receiving chips, wherein
the carrier plate is divided into a first region and a second region surrounding the first region;
the plurality of light sources are arranged in the first region, wherein the plurality of light sources are a plurality of blue light flip-chips;
the plurality of non-visible light emitting chips located on two adjacent sides of the first region and the plurality of light receiving chips located on the other two adjacent sides of the first region are arranged in the second region; and
the plurality of non-visible light emitting chips are in a one-to-one correspondence with the plurality of light receiving chips.

15. The display device according to claim 14, wherein a transparent protective adhesive layer is arranged on the carrier plate.
